(19) United States
(12) Patent Application Publication
(10) Pub. No.: US 2026/0221211 A1
(43) Pub. Date: Jul. 30, 2026

(54) METHOD FOR DETERMINING TIMING PARAMETER OF MEMORY CHIP, CONTROLLER, DEVICE, AND MEDIUM

(71) Applicant: Shenzhen Rayson Technology Co., Ltd., Shenzhen (CN)

(72) Inventor: Jun Wang, Shenzhen (CN)

(21) Appl. No.: 19/403,887

(22) Filed: Nov. 30, 2025

(30) Foreign Application Priority Data
Jan. 20, 2025 (CN) 2025100822818

(51) Int. Cl. G11C 29/12; G11C 29/36

(52) U.S. Cl. CPC G11C 29/12015; G11C 29/1201; G11C 29/36

(57) ABSTRACT

This application discloses a method for determining timing parameters of a memory chip, as well as a controller, a device, and a medium, relating to the field of chip testing technology. The method comprises performing row-column position determination processing based on a current transmission delay determined by an initial transmission delay and an initial step value to determine a memory location; updating to obtain an updated delay test range and an updated step value according to a verification result obtained from read-write verification based on the memory location and a test pattern; the updated delay test range comprises a third end value and a fourth end value greater than the third end value; in the case where the current step value is greater than or equal to a preset step threshold, performing row-column position determination processing, read-write verification processing.

### TECHNICAL FIELD

This application pertains to the field of chip testing technology, particularly relating to a method for determining timing parameters of a memory chip, as well as a controller, a device, and a medium.

### BACKGROUND

A DDR (Double Data Rate) chip is a type of synchronous dynamic random-access memory. In a DDR chip, the memory location is determined within the data storage cells through the use of row address strobe control signals and column address strobe control signals. During the addressing process to determine the memory location, the row address strobe control signal is typically sent first. After a certain time interval, which ensures that the DDR chip has sufficient time for precharging and opening the required row, and under the condition that the row address strobe control signal is stable, the column address strobe control signal is then sent to select the memory location. This time interval is an important timing parameter of the DDR chip, indicating the transmission delay between sending the row address strobe control signal and sending the column address strobe control signal. If this timing parameter is configured too small, the column address strobe control signal may be sent before the row address strobe control signal has stabilized. In such cases, the DDR chip will not be able to correctly receive the column address strobe control signal and will fail to accurately identify the combination of row and column, resulting in the inability to fully and correctly write data to the target memory location. Additionally, different DDR chips have varying timing parameters (denoted as t), and there are different requirements for the timing parameters of DDR chips on different platforms. Some platforms may not be compatible with certain DDR chips. Therefore, it is necessary to individually test and determine the value of the timing parameter t for each DDR chip before it leaves the factory, in order to facilitate the selection of compatible DDR chips for the platform. Typically, the target delay is verified as the timing parameter t by individually testing candidate delays. However, this testing method is inefficient and difficult to ensure testing accuracy.

### SUMMARY

This application aims to address at least one of the technical problems existing in the prior art. To this end, this application proposes a method for determining timing parameters of a memory chip, as well as a controller, a device, and a medium, which can improve the testing efficiency and accuracy of determining the minimum reference value for the timing parameters of the memory chip, providing a reliable reference in the process of selecting compatible memory chips for a platform.

In a first aspect, embodiments of this application provide a method for determining timing parameters of a memory chip, comprising:
adding an initial transmission delay determined by a pre-configured initial delay test range to a preset initial step value to obtain a current transmission delay;
performing row-column position determination processing based on the current transmission delay to determine a memory location;
performing read-write verification processing on the memory chip under test based on the memory location and a test pattern to obtain a verification result;
performing a first updating process on the current delay test range to obtain an updated delay test range according to the verification result, and performing a second updating process on the initial step value to determine an updated step value; the updated delay test range comprises a third end value and a fourth end value greater than the third end value;
adding the third end value and the updated step value to obtain an updated transmission delay when the current step value is greater than or equal to a preset step threshold; sequentially performing the row-column position determination processing, the read-write verification processing, the first updating process, and the second updating process based on the updated transmission delay when the updated transmission delay is less than the fourth end value;
determining the most recently updated transmission delay that resulted in a passed verification as the target transmission delay until the updated step value is less than the preset step threshold, and outputting the target transmission delay as the minimum reference value for the timing parameters of the memory chip.

According to some embodiments of this application, the performing row-column position determination processing based on the current transmission delay to determine a memory location comprises:
sending a row address strobe control signal to determine a row address;
sending a column address strobe control signal to determine a column address after the current transmission delay;
determining the memory location based on the row address and the column address.

According to some embodiments of this application, the performing read-write verification processing on the memory chip under test based on the memory location and the test pattern to obtain the verification result comprises:
writing the preset test pattern to the memory location;
performing a read operation on the memory location to obtain a read-back pattern after storing the test pattern at the memory location;
determining the verification result as a passed verification when the test pattern is consistent with the read-back pattern;
determining the verification result as a verification error when the test pattern is inconsistent with the read-back pattern.

According to some embodiments of this application, the current delay test range comprises a first end value and a second end value greater than the first end value.

The performing the first updating process on the current delay test range to obtain an updated delay test range comprises:
determining the current delay test range when the verification result is a “passed verification”; determining the current transmission delay as an updated second end value;
updating the second end value of the current delay test range based on the updated second end value to obtain the updated delay test range; the updated delay test range is determined based on the first end value of the current delay test range and the updated second end value.

According to some embodiments of this application, the current delay test range comprises a first end value and a second end value greater than the first end value.

The performing the first updating process on the current delay test range to obtain the updated delay test range comprises:
determining the current delay test range when the verification result is a “verification error”;
determining the current transmission delay as an updated first end value;
updating the first end value of the current delay test range based on the updated first end value to obtain the updated delay test range; the updated delay test range is determined based on the updated first end value and the second end value of the current delay test range.

According to some embodiments of this application, the verification result is a “passed verification” or a “verification error”; The performing the second updating process on the initial step value to determine the updated step value comprises:
determining a first control coefficient as 0 and a second control coefficient as 1, counting the number of passed read-write verification processes with a passed verification result when the verification result is a “verification passed”; calculating the updated step value based on a preset step value updating formula, the first control coefficient, the second control coefficient, and the number of passed read-write verification processes with a passed verification result;
determining the first control coefficient as 1 and the second control coefficient as 0 when the verification result is a “verification error”, and calculating the updated step value based on the preset step value updating formula, the first control coefficient, and the second control coefficient.

According to some embodiments of this application, the preset step value updating formula is:

$${t}_{1} = {A}_{1} {t}_{0} + {A}_{2} ( {t}_{0} * \frac{1}{{2}^{n}} ) ;$$

wherein, t₁ represents the updated step value, t₀ represents the initial step value, A₁ represents the first control coefficient, A₂ represents the second control coefficient, and n represents the number of passed read-write verification processes with a passed verification result.

In a second aspect, embodiments of this application provide a controller, comprising at least one processor and a memory configured for communication connection with the at least one processor. The memory stores instructions executable by the at least one processor. These instructions, when executed by the at least one processor, enable the at least one processor to perform the method for determining timing parameters of a memory chip as described in any embodiment of the first aspect.

In a third aspect, embodiments of this application provide an electronic device, comprising the controller as described in any embodiment of the second aspect.

In a fourth aspect, embodiments of this application provide a computer-readable storage medium. The computer-readable storage medium stores computer-executable instructions that, when executed by a computer, cause the computer to perform the method for determining timing parameters of a memory chip as described in any embodiment of the first aspect.

The embodiments of this application comprise the following process during the testing and determination of timing parameters of a memory chip using a controller. First, the initial transmission delay determined by a pre-configured initial delay test range is added to a preset initial step value to obtain the current transmission delay. Second, row-column position determination processing is performed based on the current transmission delay to determine the memory location. Next, read-write verification processing is performed on the memory chip under test based on the memory location and a test pattern to obtain a verification result. The verification result provides a reference for subsequent first and second updating processes. Then, according to the verification result, the first updating process is performed on the current delay test range to obtain an updated delay test range, and the second updating process is performed on the initial step value to determine an updated step value. The updated delay test range comprises a third end value and a fourth end value greater than the third end value. In the case where the current step value is greater than or equal to a preset step threshold, the third end value and the updated step value are added to obtain an updated transmission delay. When the updated transmission delay is less than the fourth end value, row-column position determination processing, read-write verification processing, the first updating process, and the second updating process are sequentially performed based on the updated transmission delay. Finally, until the updated step value is less than the preset step threshold, the most recently updated transmission delay that resulted in a passed verification is determined as the target transmission delay, which is output as the minimum reference value for the timing parameters of the memory chip. Compared to the method of individually verifying candidate delays within an initial delay test range based on a fixed step value to determine the target transmission delay, this application employs a step value updating mechanism to continuously update the initial step value to obtain an updated step value, thereby enabling efficient testing while accurately determining the timing parameters of the memory chip. This provides a reliable reference in the process of selecting compatible memory chips for a platform. In other words, the embodiments of this application can improve the testing efficiency and accuracy of determining the minimum reference value for the timing parameters of a memory chip, providing a reliable reference in the process of selecting compatible memory chips for a platform.

### BRIEF DESCRIPTION OF THE DRAWINGS

FIG. 1 is a schematic structural diagram of a testing system for achieving the determination of timing parameters of a memory chip, provided in one embodiment of this application;

FIG. 2 is a schematic flow diagram of a method for determining timing parameters of a memory chip, provided in one embodiment of this application;

FIG. 3 is a schematic step—flow diagram of the first updating process when the verification result indicates a successful verification, provided in one embodiment of this application;

FIG. 4 is a schematic step—flow diagram of the first updating process when the verification result indicates a verification error, provided in one embodiment of this application;

FIG. 5 is a schematic step—flow diagram of the second updating process, provided in one embodiment of this application; and

FIG. 6 is a schematic hardware structural diagram of an electronic device, provided in one embodiment of this application.

### DETAILED DESCRIPTION

In order to make the objectives, technical solutions, and advantages of this application clearer, a further detailed description of this application is provided below in conjunction with the accompanying drawings and embodiments.

It should be understood that in the description of this application, when directional descriptions are involved, such as up, down, front, back, left, right, and other indicated directions or positional relationships, they are based on the directions or positional relationships shown in the accompanying drawings. These are merely for the convenience of describing this application and simplifying the description, rather than indicating or implying that the referred-to device or component must have a specific orientation or be constructed and operated in a specific orientation. Therefore, they should not be construed as a limitation on this application.

It should be noted that although logical sequences are shown in the flowcharts in the description of this application, in some cases, the steps shown or described may be executed in a sequence different from that in the flowcharts. In the description of this application, “several” means one or more, and “multiple” means two or more. The terms “first” and “second” are used only for the purpose of distinguishing technical features and should not be construed as indicating or implying relative importance or implicitly indicating the quantity or sequential relationship of the indicated technical features.

Unless otherwise defined, all technical and scientific terms used herein have the same meanings as commonly understood by those skilled in the technical field to which this application pertains. The terms used herein are only for the purpose of describing the embodiments of this application and are not intended to limit this application.

This application provides a method for determining timing parameters of a memory chip, a controller, an electronic device, and a computer-readable storage medium, which relate to the field of memory chip testing technology. The method comprises: performing row-column position determination processing based on the current transmission delay determined by the initial transmission delay and the initial step value to determine the memory location; updating to obtain an updated delay test range and an updated step value according to the verification result obtained from read-write verification based on the memory location and a test pattern; the updated delay test range comprises a third end value and a fourth end value greater than the third end value; in the case where the current step value is greater than or equal to a preset step threshold, performing row-column position determination processing, read-write verification processing, and updating processing based on the updated transmission delay, which is determined by the third end value and the updated step value and is less than the fourth end value; determining the minimum reference value for the timing parameters of the memory chip until the updated step value is less than the preset step threshold. This can improve the testing efficiency and accuracy of determining the minimum reference value for the timing parameters of the memory chip.

Further elaboration on the embodiments of this application is provided below in conjunction with the accompanying drawings.

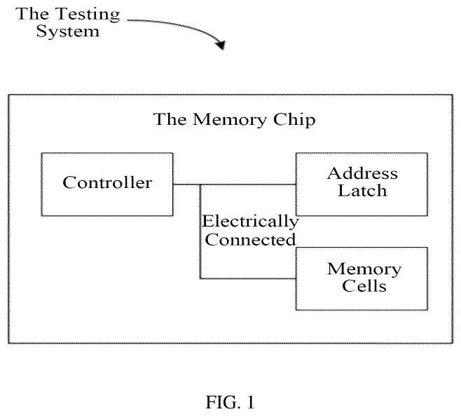

As shown in FIG. 1, the testing system comprises a controller and a memory chip under test.

The memory chip comprises an address latch and memory cells; the controller is electrically connected to both the address latch and the memory cells respectively; the memory cells form a memory array.

Specifically, the memory chip is a DDR (Double Data Rate) chip, which is a type of synchronous dynamic random-access memory.

Specifically, the address latch is used to receive row address strobe control signals and select the row address indicated in the row address strobe control signals to access a specific row in the memory cells. It is also used to receive column address strobe control signals and select the column address indicated in the column address strobe control signals to access a specific column in the memory cells, thereby determining the storage location to be accessed in the memory cells.

Specifically, the memory cells are used to store data.

Specifically, the controller is used to execute the method for determining timing parameters of a memory chip provided in the embodiments of this application, thereby improving the testing efficiency and accuracy of determining the minimum reference value for the timing parameters of the memory chip and providing a reliable reference in the process of selecting compatible memory chips for a platform. It should be noted that the controller capable of executing the method for determining timing parameters of a memory chip provided in the embodiments of this application can be an internal controller of the memory chip or a controller located either inside or outside the memory chip (such as a controller in a host computer or a testing machine). This application does not impose specific restrictions on the type of the controller.

Those skilled in the art can understand that the system architecture shown in the figures does not constitute a limitation on the embodiments of this application. The system may comprise more or fewer components than those shown in the figures, or some components may be combined, or the components may be arranged differently.

The system embodiments described above are merely illustrative. The units described as separate components may or may not be physically separated, that is, they may be located in the same place or distributed across multiple network units. Depending on actual needs, some or all of the modules can be selected to achieve the objectives of the embodiments of this application.

Those skilled in the art can understand that the system architecture and application scenarios described in the embodiments of this application are for the purpose of more clearly illustrating the technical solutions of this application and do not constitute limitations on the technical solutions provided in the embodiments of this application. As system architectures evolve and new application scenarios emerge, the technical solutions provided in the embodiments of this application are also applicable to similar technical problems.

Based on the above system architecture, various embodiments of the method for determining timing parameters of a memory chip in this application are presented below.

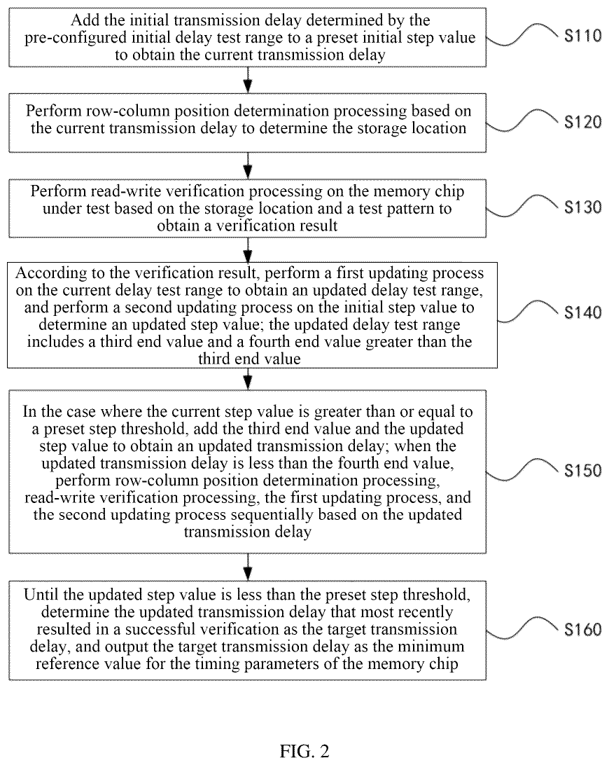

In a first aspect, as shown in FIG. 2, the method for determining timing parameters of the memory chip can be applied to the controller shown in FIG. 1. The method for determining timing parameters of the memory chip may comprise, but is not limited to, steps S110 to S160:
Step S110: adding the initial transmission delay determined by the pre-configured initial delay test range to a preset initial step value to obtain the current transmission delay;
Step S120: performing row-column position determination processing based on the current transmission delay to determine the storage location;
Step S130: perform read-write verification processing on the memory chip under test based on the storage location and a test pattern to obtain a verification result;
Step S140: according to the verification result, performing a first updating process on the current delay test range to obtain an updated delay test range, and performing a second updating process on the initial step value to determine an updated step value; wherein the updated delay test range comprises a third end value and a fourth end value greater than the third end value;
Step S150: in the case where the current step value is greater than or equal to a preset step threshold, adding the third end value and the updated step value to obtain an updated transmission delay; when the updated transmission delay is less than the fourth end value, performing row-column position determination processing, read-write verification processing, the first updating process, and the second updating process sequentially based on the updated transmission delay;
Step S160: until the updated step value is less than the preset step threshold, determining the updated transmission delay that most recently resulted in a successful verification as the target transmission delay, and outputting the target transmission delay as the minimum reference value for the timing parameters of the memory chip.

Specifically, the initial delay test range ranges from 0 to a preset maximum test value; thus, the initial transmission delay is 0. The initial step value is greater than the preset step threshold. The preset maximum test value can be pre-configured, and the current transmission delay under test does not exceed the preset maximum test value; this application does not impose specific restrictions on the value of the preset maximum test value.

Specifically, the preset step threshold is the minimum step value allowed by the protocol.

Specifically, the test pattern is preset by test personnel through a configuration interface. The test pattern can be, for example, 0XA5A5A5A5A5 or 0XFFFFFFFF, etc. Therefore, this application does not impose specific restrictions on the type of the test pattern.

In one embodiment, the method for determining timing parameters of a memory chip further comprises: after obtaining the updated transmission delay, when the updated transmission delay is greater than or equal to the fourth end value of the updated delay test range, the updated transmission delay that most recently resulted in a successful verification is determined as the target transmission delay, and the target transmission delay is output as the minimum reference value for the timing parameters of the memory chip.

It can be understood that the timing parameters of the memory chip obtained through testing in the embodiments of this application are used to indicate the transmission delay between sending a row address strobe control signal and sending a column address strobe control signal. Different platforms have varying requirements for this timing parameter t of the memory chip. For example, if a certain platform requires the reference value of the timing parameter of the memory chip to be at least 10 ns, then memory chips with a timing parameter greater than or equal to the reference value of 10 ns can be suitable for that platform; whereas memory chips with a timing parameter less than the reference value of 10 ns are not suitable for that platform. It is evident that after step S160, the timing parameters of the memory chip obtained through testing can provide reliable references for assembly personnel in the process of selecting suitable memory chips for a platform.

Through steps S110 to S160, in the process of using a controller to test and determine the timing parameters of the memory chip, firstly, the initial transmission delay determined by the pre-configured initial delay test range is added to a preset initial step value to obtain the current transmission delay; secondly, row-column position determination processing is performed based on the current transmission delay to determine the storage location; next, read-write verification processing is performed on the memory chip under test based on the storage location and a test pattern to obtain a verification result; the verification result provides a reference for subsequent first and second updating processes; then, according to the verification result, the current delay test range is subjected to a first updating process to obtain an updated delay test range, and the initial step value is subjected to a second updating process to determine an updated step value; the updated delay test range comprises a third end value and a fourth end value greater than the third end value; in the case where the current step value is greater than or equal to a preset step threshold, the third end value and the updated step value are added to obtain an updated transmission delay; when the updated transmission delay is less than the fourth end value, row-column position determination processing, read-write verification processing, the first updating process, and the second updating process are performed sequentially based on the updated transmission delay; finally, until the updated step value is less than the preset step threshold, the updated transmission delay that most recently resulted in a successful verification is determined as the target transmission delay, and the target transmission delay is output as the minimum reference value for the timing parameters of the memory chip. Compared to determining the target transmission delay by sequentially verifying each candidate delay within the initial delay test range based on a fixed step value, this application employs a step value updating mechanism to continuously update the initial step value to obtain an updated step value, thereby enabling efficient testing and more accurately determining the timing parameters of the memory chip, providing reliable references in the process of selecting suitable memory chips for a platform. Therefore, the embodiments of this application can improve the testing efficiency and accuracy of determining the minimum reference value for the timing parameters of the memory chip, providing reliable references in the process of selecting suitable memory chips for a platform.

According to some embodiments of this application, step S120 is further elaborated as follows: Step S120, which involves performing row-column position determination processing based on the current transmission delay to determine the storage location, comprises, but is not limited to, steps S121 to S123;
Step S121: sending a row address strobe control signal to determine the row address;
Step S122: sending a column address strobe control signal to determine the column address after the current transmission delay;
Step S123: determining the storage location based on the row address and the column address.

It can be understood that the row address strobe control signal indicates the row address of the storage location to be accessed, while the column address strobe control signal indicates the column address of the storage location to be accessed. Test personnel can set the storage location according to their requirements; therefore, this application does not impose specific restrictions on the row address and column address.

It can also be understood that if the value of the current transmission delay is too small, the row address strobe control signal may not have stabilized, and there may not have been sufficient time for precharging and opening the required row in the memory chip under test. This makes it difficult to correctly receive the column address strobe control signal and determine the correct storage location, leading to errors in subsequent read-write verification processing based on the storage location. Therefore, in the embodiments of this application, through steps S121 to S123, the row address strobe control signal and the column address strobe control signal are sent sequentially based on the current transmission delay to determine the storage location, laying the foundation for subsequent read-write verification processing.

According to some embodiments of this application, step S130 is further elaborated as follows: Step S130, which involves performing read-write verification processing on the memory chip under test based on the storage location and a test pattern to obtain a verification result, comprises, but is not limited to, steps S131 to S134:
Step S131: writing a preset test pattern to the storage location;
Step S132: performing a read operation on the storage location to obtain a read-back pattern after storing the test pattern at the storage location;
Step S133: determine the verification result as a passed verification if the test pattern matches the read-back pattern;
Step S134: determining the verification result as a verification error if the test pattern does not match the read-back pattern.

Specifically, after determining the storage location, the preset test pattern is written to the storage location through a write operation. Subsequently, a read operation is performed on the storage location to obtain the read-back pattern, and the verification result is determined based on a comparison between the test pattern and the read-back pattern.

Specifically, when determining whether the test pattern matches the read-back pattern, the following methods can be adopted. First, the test pattern and the read-back pattern can be directly compared to determine if they match. Second, an exclusive-OR (XOR) operation can be performed bit by bit on the test pattern and the read-back pattern, and the result of the XOR operation can be used to determine if the test pattern matches the read-back pattern. If the result of the XOR operation is all zeros, it is determined that the test pattern matches the read-back pattern; otherwise, it is determined that they do not match. Third, a cyclic redundancy check (CRC) algorithm can be used to calculate a first checksum for the test pattern and a second checksum for the read-back pattern. If the first checksum equals the second checksum, it is determined that the test pattern matches the read-back pattern; if they are not equal, it is determined that they do not match. Therefore, this application does not impose specific restrictions on the method used to determine whether the test pattern matches the read-back pattern.

It can be understood that the timing parameters of a memory chip have a certain range of values. Generally, a platform will require the minimum reference value for the timing parameters of the memory chip. To subsequently screen memory chips suitable for the platform based on timing parameters, this embodiment of the application tests and determines the minimum reference value for the timing parameters. Specifically, further elaborating on steps S133 and S134, if the verification result is a passed verification, it is determined that the current transmission delay used in step S122 is a valid value for the timing parameters of the memory chip under test; if the verification result is a verification error, it is determined that the current transmission delay used in step S122 is an invalid value for the timing parameters of the memory chip under test.

Through steps S131 to S134, a verification result can be obtained to determine whether the current transmission delay is acceptable, laying a reference foundation for subsequent first and second updating processes.

Furthermore, the first updating process and the second updating process in step S140 are further elaborated. The current delay test range comprises a first end value and a second end value greater than the first end value.

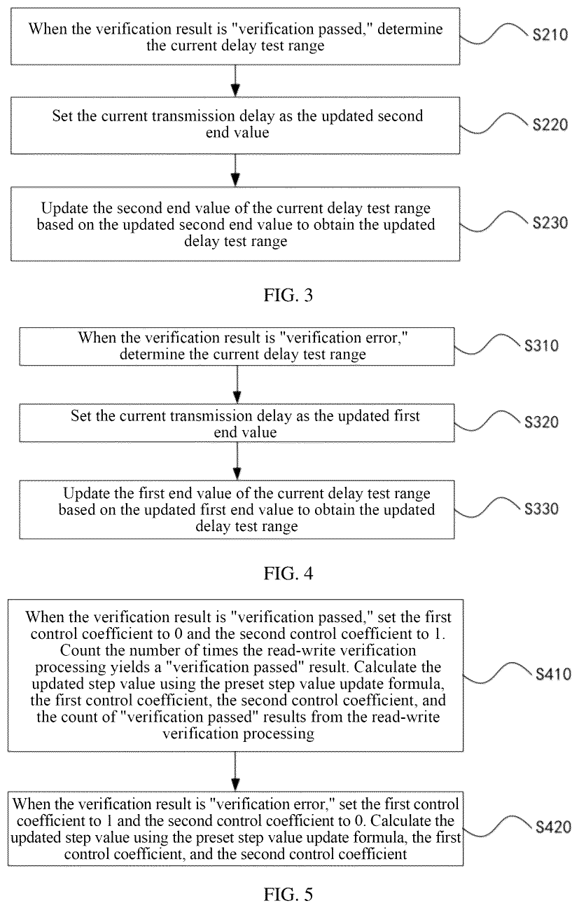

According to some embodiments of this application, as illustrated in FIG. 3, the first updating process is performed on the current delay test range to obtain an updated delay test range, comprising but not limited to steps S210 to S230:
Step S210: determining the current delay test range when the verification result is a passed verification;
Step S220: setting the current transmission delay as the updated second end value;
Step S230: updating the second end value of the current delay test range based on the updated second end value to obtain the updated delay test range.

It can be understood that after completing the read-write verification processing, if the verification result is a passed verification, it is determined that the current transmission delay used in step S122 is a valid value for the timing parameters of the memory chip under test. Subsequently, the current transmission delay is set as the updated second end value, and the updated delay test range is determined based on the first end value of the current delay test range and the updated second end value. The values at both ends of the updated delay test range are recorded as: the third end value (equivalent to the first end value of the current delay test range) and the fourth end value (equivalent to the updated second end value).

Through steps S210 to S230, when the verification result is a passed verification,” the updated delay test range is determined, laying the foundation for determining the updated transmission delay.

According to some embodiments of this application, as shown in FIG. 4, the first updating process is performed on the current delay test range to obtain an updated delay test range, including but not limited to steps S310 to S330;
Step S310: determining the current delay test range when the verification result is a verification error;
Step S320: setting the current transmission delay as the updated first end value;
Step S330: update the first end value of the current delay test range based on the updated first end value to obtain the updated delay test range.

It can be understood that after completing the read-write verification processing, when the verification result is “verification error,” it is determined that the current transmission delay used in step S122 is an invalid value for the timing parameters of the memory chip under test. Subsequently, the current transmission delay is set as the updated first end value, and the updated delay test range is determined based on the updated first end value and the second end value of the current delay test range. The values at both ends of the updated delay test range are recorded as: the third end value (equivalent to the updated first end value) and the fourth end value (equivalent to the second end value of the current delay test range).

Through steps S310 to S330, when the verification result is a “verification error,” the updated delay test range is determined, laying the foundation for determining the updated transmission delay.

According to some embodiments of this application, the verification result can be “verification passed” or “verification error.” As shown in FIG. 5, the second updating process is performed on the initial step value to determine the updated step value, including but not limited to steps S410 to S420;
Step S410: when the verification result is “verification passed,” setting the first control coefficient to 0 and the second control coefficient to 1; counting the number of times the read-write verification processing yields a “verification passed” result; calculating the updated step value using the preset step value update formula, the first control coefficient, the second control coefficient, and the count of “verification passed” results from the read-write verification processing;
Step S420: when the verification result is a “verification error,” setting the first control coefficient to 1 and the second control coefficient to 0; calculating the updated step value using the preset step value update formula, the first control coefficient, and the second control coefficient.

According to some embodiments of this application, the preset step value update formula is shown below:

$${t}_{1} = {A}_{1} {t}_{0} + {A}_{2} ( {t}_{0} * \frac{1}{{2}^{n}} ) ;$$

wherein t₁ is the updated step value, to is the initial step value, A₁ is the first control coefficient, A₂ is the second control coefficient, and n is the count of “verification passed” results from the read-write verification processing.

It can be understood that when determining the target transmission delay by verifying each delay within the initial delay test range based on a fixed step value, if the fixed step value is too small, although the minimum reference value for the timing parameters of the memory chip obtained through testing will be relatively accurate, multiple tests will be required to determine the minimum reference value, resulting in low overall testing efficiency. Conversely, if the fixed step value is too large, while a usable reference value for the timing parameters can be obtained relatively quickly, the large step value may cause smaller reference values for the timing parameters to be missed during testing, leading to significant deviations between the obtained reference value and the true minimum reference value, thus reducing accuracy. This application implements a dynamic step value update mechanism through steps S410 to S420, continuously updating the initial step value based on the verification result of each read-write verification processing to obtain the updated step value. This approach enables efficient testing while accurately determining the minimum reference value for the timing parameters of the memory chip.

An example below is provided to illustrate the overall process of the method for determining the timing parameters of a memory chip according to an embodiment of this application.

Step S501: the pre-configured initial delay test range is 0 to 50 ns, the initial transmission delay TO is 0, the preset initial step value t0 is 5 ns, and the preset step threshold is 0.5 ns.

Step S502: the initial transmission delay and the initial step value are added to obtain the current transmission delay T1 as 5 ns.

Step S503: based on the current transmission delay T1 of 5 ns, the storage location is determined through row and column position determination processing, and then read-write verification processing is performed to obtain the verification result.

Step S504: when the verification result is “verification error,” the first updating process is performed: determining the current delay test range as the initial delay test range (0 to 50 ns); setting the current transmission delay T1 (5 ns) as the updated first end value; determining the updated delay test range (5 ns to 50 ns) based on the updated first end value (5 ns) and the second end value (50 ns) of the current delay test range. The second updating process is performed: setting the first control coefficient A₁ to 1 and the second control coefficient A₂ to 0; these values are substituted into the preset step value update formula:

$${t}_{1} = {A}_{1} {t}_{0} + {A}_{2} ( {t}_{0} * \frac{1}{{2}^{n}} ) ;$$

the updated step value t₁ is obtained as being equal to the initial step value t₀=5 ns. Since the updated step value t₁ (5 ns) is greater than the preset step threshold (0.5 ns), the third end value (5 ns) of the updated delay test range is added to the updated step value t₁ (5 ns) to obtain the current transmission delay T1 as 10 ns.

Step S505: based on the current transmission delay T1 of 10 ns, the storage location is determined through row and column position determination processing, and read-write verification processing is performed to obtain the verification result; when the verification result is “verification error,” the same first updating process as in step S504 is performed to obtain the updated delay test range (10 ns to 50 ns); the same second updating process as in step S504 is performed to determine the updated step value t₁ (5 ns); the third end value (10 ns) of the updated delay test range is added to the updated step value t₁ (5 ns) to obtain the current transmission delay T1 as 15 ns.

Step S506: based on the current transmission delay T1 of 15 ns, the storage location is determined through row and column position determination processing, and then read-write verification processing is performed to obtain the verification result; when the verification result is “verification error,” the same first updating process as in step S504 is performed to obtain the updated delay test range (15 ns to 50 ns); the same second updating process as in step S504 is performed to determine the updated step value t₁ (5 ns); the third end value (15 ns) of the updated delay test range is added to the updated step value t₁ (5 ns) to obtain the current transmission delay T1 as 20 ns.

Step S507: based on the current transmission delay T1 of 20 ns, the storage location is determined through row and column position determination processing, and then read-write verification processing is performed to obtain the verification result; when the verification result is “verification error,” the same first updating process as in step S504 is performed to obtain the updated delay test range (20 ns to 50 ns); the same second updating process as in step S504 is performed to determine the updated step value t₁ (5 ns); the third end value (20 ns) of the updated delay test range is added to the updated step value t₁ (5 ns) to obtain the current transmission delay T1 as 25 ns.

Step S508: based on the current transmission delay T1 of 25 ns, the storage location is determined through row and column position determination processing, and then read-write verification processing is performed to obtain the verification result; when the verification result is “verification passed,” the first updating process is performed: based on step S507, the current delay test range as 20 ns to 50 ns is determined; the current transmission delay T1 (25 ns) is set as the updated second end value; the updated delay test range (20 ns to 25 ns) is determined based on the updated second end value (25 ns) and the first end value (20 ns) of the current delay test range. The second updating process is performed: the first control coefficient A₁ is set to 0 and the second control coefficient A₂ is set to 1; the number n of “verification passed” results from the read-write verification processing is counted, wherein n=1; these values are substituted into the preset step value update formula:

$${t}_{1} = {A}_{1} {t}_{0} + {A}_{2} ( {t}_{0} * \frac{1}{{2}^{n}} ) ;$$

the updated step value t1 is obtained as t1=(t0)*½. Given that t0 is 5 ns, the updated step value t₁ (2.5 ns) is obtained, and this updated step value t₁ (2.5 ns) is greater than the preset step threshold (0.5 ns). Thus, by adding the third end value (20 ns) of the updated delay test range (from 20 ns to 25 ns) to the updated step value t₁ (2.5 ns), the current transmission delay T1 is determined to be 22.5 ns.

Step S509: based on the current transmission delay T1 of 22.5 ns, the storage location is determined through row and column position determination processing, and then read-write verification processing is performed to obtain the verification result; when the verification result is “verification passed,” the same first updating process as in step S508 is performed to obtain the updated delay test range (20 ns to 22.5 ns); the same second updating process as in step S508 is performed to determine the count of “verification passed” results as 2 and the updated step value t₁ as 1.25 ns; the third end value (20 ns) of the updated delay test range is added to the updated step value t₁ (1.25 ns) to obtain the current transmission delay T1 as 21.25 ns.

Step S510: based on the current transmission delay T1 of 21.25 ns, the storage location is determined through row and column position determination processing, and then read-write verification processing is performed to obtain the verification result; when the verification result is “verification passed,” the same first updating process as in step S508 is performed to obtain the updated delay test range (20 ns to 21.25 ns); the same second updating process as in step S508 is performed to determine the count of “verification passed” results as 3 and the updated step value t₁ as 0.625 ns; the third end value (20 ns) of the updated delay test range is added to the updated step value t₁ (0.625 ns) to obtain the current transmission delay T1 as 20.625 ns.

Step S511: based on the current transmission delay T1 of 20.625 ns, the storage location is determined through row and column position determination processing, and then read-write verification processing is performed to obtain the verification result; when the verification result is “verification passed,” the same first updating process as in step S508 is performed to obtain the updated delay test range (20 ns to 20.625 ns); the same second updating process as in step S508 is performed to determine the count of “verification passed” results as 4 and the updated step value t₁ as 0.3125 ns; since 0.3125 ns is less than the preset step threshold (0.5 ns), the most recent transmission delay that yielded a “verification passed” result (20.625 ns) is set as the target transmission delay; the target transmission delay as the minimum reference value for the timing parameters of the memory chip under test is output.

Additionally, if the verification result from the read-write verification processing based on the current transmission delay T1 of 21.25 ns in step S510 is “verification error,” the same first updating process as in step S504 is performed to obtain the updated delay test range (21.25 ns to 22.5 ns). The same second updating process as in step S504 is performed to determine the updated step value t₁ (5 ns). The third end value (21.25 ns) of the updated delay test range is added to the updated step value t₁ (5 ns) to obtain the current transmission delay T1 as 26.25 ns. Since this value exceeds the fourth end value (22.5 ns) of the updated delay test range (21.25 ns to 22.5 ns), the most recent transmission delay that yielded a “verification passed” result (22.5 ns) from step S509 is set as the target transmission delay. The target transmission delay as the minimum reference value for the timing parameters of the memory chip is output.

It can be understood that when the minimum reference value for the timing parameters of a memory chip under test is approximately 20.625 ns, the method according to an embodiment of this application can determine the minimum reference value for the timing parameters through a total of eight read-write verification processing steps from step S501 to step S511. In contrast, if a fixed step value of 0.5 ns is used starting from 0 to determine the transmission delay and perform read-write verification processing after determining the storage location through row and column position determination processing, 41 read-write verification processing steps would be required.

Thus, this embodiment of the application can improve the testing efficiency and accuracy of determining the minimum reference value for the timing parameters of a memory chip.

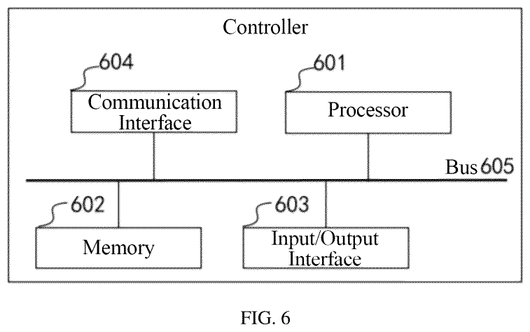

As shown in FIG. 6, the present disclosure also provides a controller, comprising:
a processor 601, which can be implemented using a general-purpose central processing unit (CPU), a microprocessor, an application-specific integrated circuit (ASIC), or one or more integrated circuits, etc, which is used to execute relevant programs to implement the technical solutions provided by the embodiments of this application;
a memory 602, which can be implemented in the form of a read-only memory (ROM), a static storage device, a dynamic storage device, or a random-access memory (RAM), etc, wherein the memory 602 can store the operating system and other application programs, when the technical solutions provided by the embodiments of this specification are implemented through software or firmware, the relevant program codes are stored in the memory 602, and the processor 601 is invoked to execute the method for determining timing parameters of memory chips as provided in the embodiments of this application;
an input/output interface 603, used for achieving information input and output;
a communication interface 604, configured to enable communication interaction between this device and other devices, wherein communication can be achieved through wired means (e.g., USB, network cables, etc.) or wireless means (e.g., mobile networks, Wi-Fi, Bluetooth, etc.); a bus 605, configured to transmit information among various components of the device (e.g., the processor 601, memory 602, input/output interface 603, and communication interface 604);
wherein the processor 601, the memory 602, the input/output interface 603, and communication interface 604 are internally connected for communication within the device via the bus 605.

The embodiments of this application also provide an electronic device, which comprises the controller as described above.

The embodiments of this application also provide a storage medium, which is a computer-readable storage medium. This storage medium stores a computer program, and when executed by a processor, the computer program implements the above-mentioned method for determining timing parameters of memory chips.

As a non-transitory computer-readable storage medium, the memory can be used to store non-transitory software programs and non-transitory computer-executable programs. In addition, the memory can comprise high-speed random-access memory and can also comprise non-transitory memory, such as at least one disk storage device, flash memory device, or other non-transitory solid-state storage devices. In some implementations, the memory can optionally comprise memory located remotely from the processor, and these remote memories can be connected to the processor through a network. Examples of such networks comprise, but are not limited to, the Internet, intranets, local area networks (LANs), mobile communication networks, and combinations thereof. The device embodiments described above are merely illustrative. The units described as separate components may or may not be physically separated and may be located in one place or distributed across multiple network units. Depending on actual needs, some or all of the modules can be selected to achieve the objectives of the embodiments of this solution.

Those of ordinary skill in the art can understand that all or some of the steps and systems in the methods disclosed above can be implemented as software, firmware, hardware, and appropriate combinations thereof. Some or all physical components can be implemented as software executed by a processor, such as a CPU, a digital signal processor (DSP), or a microprocessor, or as hardware, or as integrated circuits, such as ASICs. Such software can be distributed on computer-readable media, which can comprise computer storage media (or non-transitory media) and communication media (or transitory media). As known to those of ordinary skill in the art, the term “computer storage media” comprises volatile and non-volatile, removable and non-removable media implemented in any method or technology for storing information, such as computer-readable instructions, data structures, program modules, or other data. Computer storage media comprise, but are not limited to, RAM, ROM, EEPROM, flash memory, or other memory technologies, CD-ROM, digital versatile discs (DVDs), or other optical disc storage, magnetic cassettes, magnetic tapes, magnetic disk storage, or other magnetic storage devices, or any other medium that can be used to store desired information and can be accessed by a computer. In addition, as known to those of ordinary skill in the art, communication media typically comprise computer-readable instructions, data structures, program modules, or other data in modulated data signals, such as carrier waves or other transmission mechanisms, and can comprise any information delivery media.

The above provides specific descriptions of the preferred embodiments of this application, but this application is not limited to the above implementations. Those skilled in the art can make various equivalent modifications or substitutions without departing from the spirit of this application, and these equivalent modifications or substitutions are all included within the scope defined by this application.

1. A method for determining timing parameters of a memory chip, comprising:
adding an initial transmission delay determined by a pre-configured initial delay test range to a preset initial step value to obtain a current transmission delay;
performing row-column position determination processing based on the current transmission delay to determine a memory location;
performing read-write verification processing on the memory chip under test based on the memory location and a test pattern to obtain a verification result;
performing a first updating process on the current delay test range according to the verification result to obtain an updated delay test range, and performing a second updating process on the initial step value to determine an updated step value; the updated delay test range comprises a third end value and a fourth end value greater than the third end value;
when the current step value is greater than or equal to a preset step threshold, adding the third end value and the updated step value to obtain an updated transmission delay; when the updated transmission delay is less than the fourth end value, sequentially performing the row-column position determination processing, the read-write verification processing, the first updating process, and the second updating process based on the updated transmission delay;
until the updated step value is less than the preset step threshold, determining the updated transmission delay that most recently resulted in a passed verification result as a target transmission delay, and outputting the target transmission delay as a minimum reference value for the timing parameters of the memory chip.

2. The method for determining timing parameters of the memory chip according to claim 1, wherein the performing row-column position determination processing based on the current transmission delay to determine the memory location:
sending a row address strobe control signal to determine a row address;
after the current transmission delay, sending a column address strobe control signal to determine a column address;
determining the memory location according to the row address and the column address.

3. The method for determining timing parameters of the memory chip according to claim 1, wherein the performing read-write verification processing on the memory chip under test based on the memory location and the test pattern to obtain a verification result;
comprises:
writing the preset test pattern to the memory location;
performing a read operation on the memory location to obtain a read-back pattern after storing the test pattern in the memory location;
determining the verification result as a “verification passed” when the test pattern is consistent with the read-back pattern,
determining the verification result as a “verification error” when the test pattern is inconsistent with the read-back pattern.

4. The method for determining timing parameters of the memory chip according to claim 3, wherein the current delay test range comprises a first end value and a second end value greater than the first end value;
the performing the first updating process on the current delay test range to obtain the updated delay test range comprises:
determining the current delay test range when the verification result is passed;
determining the current transmission delay as the updated second end value;
updating the second end value of the current delay test range according to the updated second end value to obtain the updated delay test range; the updated delay test range is determined according to the first end value of the current delay test range and the updated second end value.

5. The method for determining timing parameters of the memory chip according to claim 3, wherein the current delay test range comprises a first end value and a second end value greater than the first end value;
the performing a first updating process on the current delay test range to obtain an updated delay test range comprises:
determining the current delay test range when the verification result is a “verification error”;
determining the current transmission delay as the updated first end value;
updating the first end value of the current delay test range according to the updated first end value to obtain the updated delay test range; the updated delay test range is determined according to the updated first end value and the second end value of the current delay test range.

6. The method for determining timing parameters of the memory chip according to claim 1, wherein the verification result is a “verification passed” or a “verification error”;
the performing the second updating process on the initial step value to determine the updated step value comprises:
determining a first control coefficient as 0 and a second control coefficient as 1, counting a number of times the read-write verification processing with a passed verification result has passed, when the verification result is a “verification passed”; calculating the updated step value according to a preset step value update formula, the first control coefficient, the second control coefficient, and the number of times the read-write verification processing with the passed verification result has passed;
determining the first control coefficient as 1 and the second control coefficient as 0 when the verification result is a “verification error”, and calculating the updated step value according to the preset step value update formula, the first control coefficient, and the second control coefficient.

7. The method for determining timing parameters of the memory chip according to claim 6, wherein the preset step value update formula is:
$${t}_{1} = {A}_{1} {t}_{0} + {A}_{2} ( {t}_{0} * \frac{1}{{2}^{n}} ) ;$$
wherein, t₁ is the updated step value, t₀ is the initial step value, A₁ is the first control coefficient, A₂ is the second control coefficient; n represents the number of times the read-write verification processing with a passed verification result has passed.

8. A controller, comprising at least one processor and a memory for communication connection with the at least one processor; the memory stores instructions executable by the at least one processor, and the instructions are executed by the at least one processor to enable the at least one processor to perform the method for determining timing parameters of the memory chip according to claim 1.

9. An electronic device, comprising the controller according to claim 8.
